(19) United States
(12) Patent Application Publication
(10) Pub. No.: US 2024/0380360 A1
(43) Pub. Date: Nov. 14, 2024

(54) A SOLAR PANEL

(71) Applicant: Solivus Limited, London (GB)

(72) Inventors: Jo PARKER-SWIFT, Kent (GB); Amy LAMBOURNE, London (GB); Ciaran COTTER, London (GB)

(21) Appl. No.: 18/683,095

(22) PCT Filed: Jun. 29, 2022
(86) PCT No.: PCT/GB2022/051678

§ 371 Date: Feb. 12, 2024

(30) Foreign Application Priority Data
Aug. 13, 2021 (GB) 2111665.2

(51) Int. Cl. H02S 30/10; H02S 20/23

(52) U.S. Cl. CPC H02S 30/10; H02S 20/23

(57) ABSTRACT

A solar panel comprising a sheet of flexible solar material (42) adhered to a support panel (10, 40) preferably formed of plastic. The support panel comprising a support layer and supports (11) formed at opposite edges of the support layer and protruding from a first side of the support layer. Holes (108) are drilled in the rails to attach the panel to a roof. The holes are preferably drilled at a level below the solar material. The panel may have through holes (105) to allow a cable (107) for the solar material to be tied to the panel.

The present invention relates to a solar panel.

In particular, it relates to a solar panel which comprises a sheet of flexible solar material. Flexible solar material contrasts with traditional solar panels which are formed of a rigid material.

This flexible material has a number of advantages over rigid solar material. In particular, in one form it is supplied on rolls and can simply be unrolled and installed, for example on a building roof, or it can be incorporated into a roof structure. Our earlier WO 2021/069710 discloses a roof panel into which the flexible solar material is incorporated. In the case of a flat roof, the flexible solar material can be unrolled and attached directly to the flat roof.

This material is much cheaper and lighter in weight than conventional rigid solar panels which have heavy backing/support layers. As such, flexible solar material can be deployed in situations where traditional solar panels are too expensive or heavy.

Whilst these flexible solar panels are easy to install on a flat roof, they are not so easy to install on an uneven roof such as a corrugated or tiled roof.

Solar panels formed of a flexible solar material on a metal backing are disclosed in CN 102127954 and US 2005/0284515. U.S. Pat. No. 5,968,287 discloses a similar structure. However, this is for a roof tile itself, not a structure which is attached to an underlying roof.

One technique that has recently been employed in order to install solar panels of this type is to create a frame which comprises a metal sheet with a pair of hollow metal rails running along opposite edges of the sheet. As far as we are aware, this technique has not been documented in a written publication. These rails are glued on one side of the metal sheet and the flexible solar sheet is glued to the opposite side of the metal sheet. This forms a lightweight panel which can be placed on the uneven roof. An installer simply needs to drill holes in the rails at a position corresponding to a localised high point of the roof (i.e., a crest of a corrugated roof or an uppermost position of a tile) and screw a screw through the rail and into the roof. Such an arrangement provides a lightweight structure which allows flexible solar material to be easily installed on an uneven roof. Alternatively, if the property owner does not wish the roof to be punctured with holes or the roof shape has thin corrugations that do not allow screws then a clamping system can be used. This allows solar panels to be used on roofs which previously did not have the structural integrity to have a rigid solar panel and have a shape to which it is difficult to attach a flexible solar panel.

The holes in the rails have to be drilled in situ as their location can only be determined once they are lined up with the corrugations in the roof. However, drilling through the rails generates high levels of heat which can damage the flexible solar material.

According to a first aspect of the present invention, there is provided a method according to claim 1.

The holes are drilled in the attachment flanges. These are spaced from and offset from the sheet of flexible solar material. This forms a longer path for any heat generated in the drilling operation. Further as the flanges are below the plane of the flexible solar material the possibility of drill cuttings damaging the solar material is reduced. Using this method, the panels can be installed very quickly as compared to conventional techniques.

The attachment flanges preferably have centrelines marked along their length and the method comprises drilling the hole on the centre line. This provides guidance for the user for where to drill the holes which further improves the speed and accuracy of the installation.

A conventional solar panel has a relatively large junction box attached in order to receive power cabling from the solar panel. This is heavy and expensive and increases the installation time. Preferably, therefore the support panel has at least one through hole at one end and the method further comprises tying a cable to the support panel by passing the tie through the through hole. The junction box is replaced with one or more through holes and ties which greatly simplifies the structure of the panel thereby significantly reducing its weight. The ties may be string, rope, elastic cables etc., but are preferably cable ties as these are easy to install reliably and are highly durable.

A further problem with the prior art is that the use of the rails of a metal such as aluminium or steel in the manufacture of the frame is relatively heavy and also increases the carbon footprint of the panels and causes recycling problems.

The metal sheet to which the flexible solar sheet is attached by an adhesive creates a parasitic capacitance between the layers. This reduces the efficiency of the solar material and can cause a static charge to build up in the frame. In order to address this, specialist inverters and earthing of the panel are required, but these introduce additional expense.

A second aspect of the invention is defined in claim 4.

The use of plastic instead of a metal sheet removes the problem of parasitic capacitance thereby removing the need for the inverters and the earthing. The use of a plastic in place of a metal provides the possibility of significant weight reductions.

The panel may further comprise one or more intermediate supports positioned between the supports at the opposite edges of the support layer and protruding from a first side of the support layer. This provides additional rigidity and support to the central part of the panel and allows larger panels to be formed.

The panel may be formed as a single piece. Alternatively, the supports may be formed as separate components attached to the support layer. As a further alternative, the panel is formed of a lower part comprising the supports and an upper part bonded to the lower part and having a flat upper face to provide the second side of the support layer.

The supports may be in the form of discrete bosses which extend along the edges of the support panel. Such a panel can be used if the spacing of the crests of the roof is known and well defined. Alternatively, the supports at the opposite edges of the support are a pair of rails. This allows the rails to be fixed at any point along their lengths as the holes in the rails can be drilled in situ at locations corresponding to the crests in the roof. Rails can still be used if the geometry of the roof is well defined as, in that case, pre-drilled holes can be formed in the rails

When the plastic rails are drilled in situ, drilling into plastic generates a fraction of the heat of drilling into metal such that the possibility of damage to the solar material is greatly reduced.

The rails can be solid blocks. However, they are preferably formed to have an open channel section. This can be formed from manufacturing techniques which involve manipulating a flat sheet into the required shape. The channels can be left open in the finished panel or can be covered, for example if the panel is formed of upper and lower panels as set out above.

If the rails are open at their ends, preferably the ends of the rails are capped to prevent ingress of water and debris. The rails may also be provided with drainage holes. Preferably wiring for the solar material is routed along the rails. This provides a convenient, well defined and well protected path for the wiring which lends itself to having well defined electrical connection points on the panels

The use of a plastic opens up more environmentally friendly solutions, such as the use of recycled plastic. In this case, heat/fire retardant additives may need to be added.

The sheet of flexible solar material is preferably encapsulated in a plastics material. In this case, the bond between the flexible solar material and the sheet of plastic of the support panel represents an adhesive joint between adjacent plastic layers. This can reduce any strain between the sheet of flexible solar material and the support panel caused by differential thermal expansion. It also allows a better choice of adhesive as the adhesive needs only to bond to a plastic, rather than to metal and plastic.

According to a third aspect of the present invention, there is provided a solar panel according to claim 19.

As set out above in respect of the first aspect, this arrangement avoids the need for a junction box thereby significantly reducing the weight, cost and complicity of the panel.

The panel preferably comprises laterally extending attachment flanges extending from the supports via which the panel is attached to a roof. This provides the benefit of the first aspect of the invention.

According to a fourth aspect of the present invention, there is provided a solar panel according to claim 21.

The presence of the first engagement feature to interlock with a complementary second engagement feature of an adjacent panel, simplifies the installation process. In particular, it provides a way to anchor an edge of the panel which does not require its own fasteners.

In its simplest form there may be a complementary pair of panels one of which has the first engagement feature and the other of which has the second engagement feature. The opposite edges of these panels may be plain or provided with other features. However, preferably, the support panel has the first engagement along a first edge and the second engagement feature along a second edge opposite to the first edge. This allows one type of panel to be produced and for multiple panels to be engaged together edge to edge.

In one example, the first engagement feature is configured to receive a fastener which, in use, will pass through a space in the engagement feature configured to receive the adjacent panel. This means that a single fastener can pass through engaged panels and anchor the panels together and to the roof.

Alternatively, the first engagement feature is configured to retain the complementary second engagement feature of an adjacent panel, and the panel is configured to receive a fastener which, in use, will pass through the panel, but not a space occupied, in use, by an adjacent panel engaged with the engagement feature. This time, once the panel is fastened in place, the edge of the fastened panel serves to retain the adjacent panel without it requiring separate fasteners.

Aspects of the invention may be combined. For example, the plastic support panel of the second aspect of the invention is preferably used in the other aspects.

As the invention relates to a panel for attachment to an existing roof, the invention also extends to a combination of a solar panel according to any of the second to fourth aspects of the invention and a plurality of fasteners for fastening the panel to a roof. It also extends to a method of attaching a solar panel according to any of the second to fourth aspects of the invention to a pre-existing roof.

An example of a solar panel in accordance with the present invention will now be described with reference to the accompanying drawings, in which:

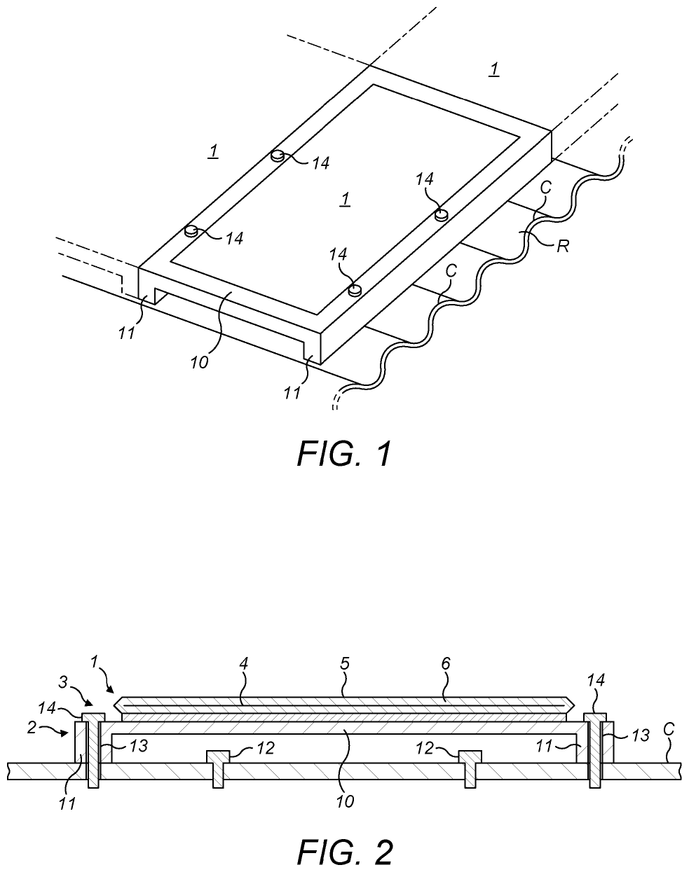

FIG. 1 is a schematic perspective view of a corrugated roof to which a solar panel according to the present invention has been attached;

FIG. 2 is a schematic cross-section of the panel and roof of FIG. 1 in a plane including a crest of the corrugated material;

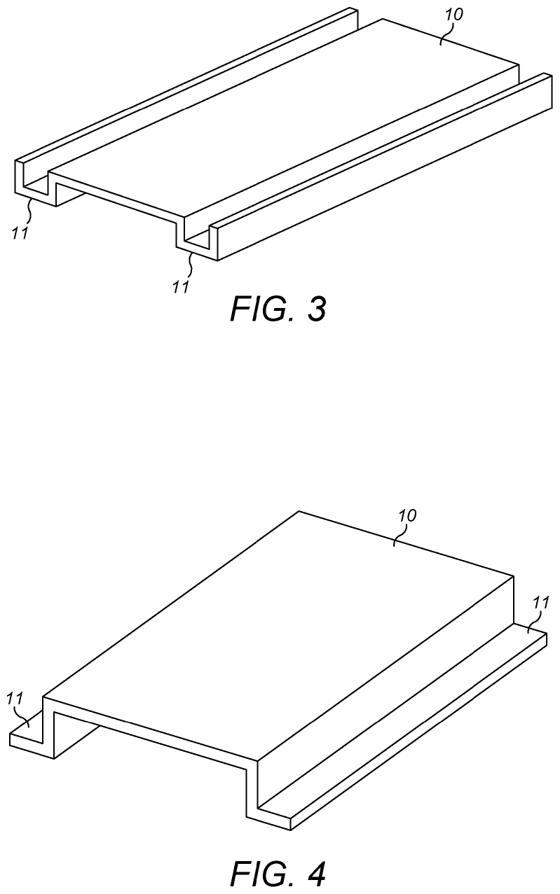

FIG. 3 is a schematic perspective view of a second example of a support panel;

FIG. 4 is a schematic perspective view of a third example of a support panel;

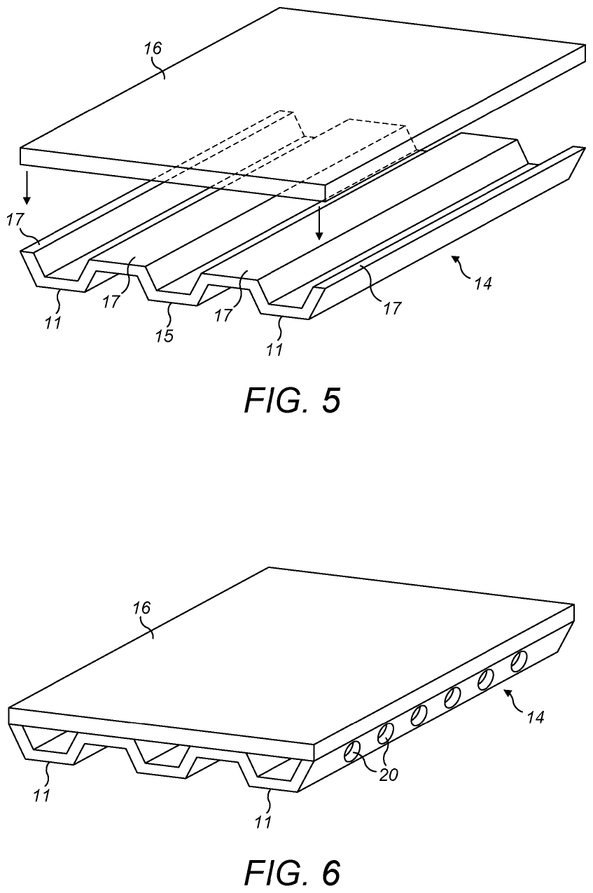

FIG. 5 is a schematic exploded perspective view of a fourth example of a support panel;

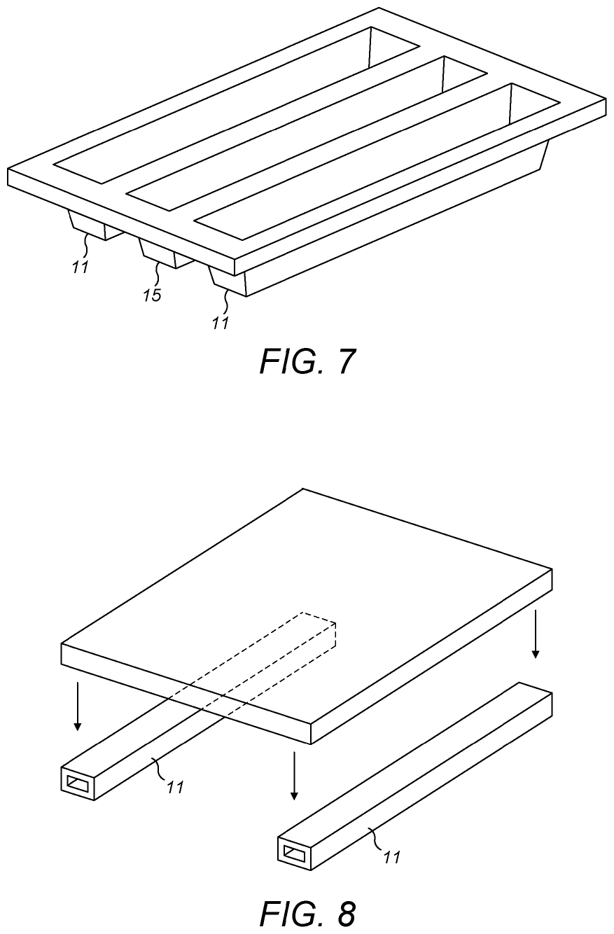

FIG. 6 is a schematic perspective view of a fifth example of a support panel;

FIG. 7 is a schematic perspective view of a sixth example of a support panel;

FIG. 8 is a schematic exploded perspective view of a seventh example of a support panel;

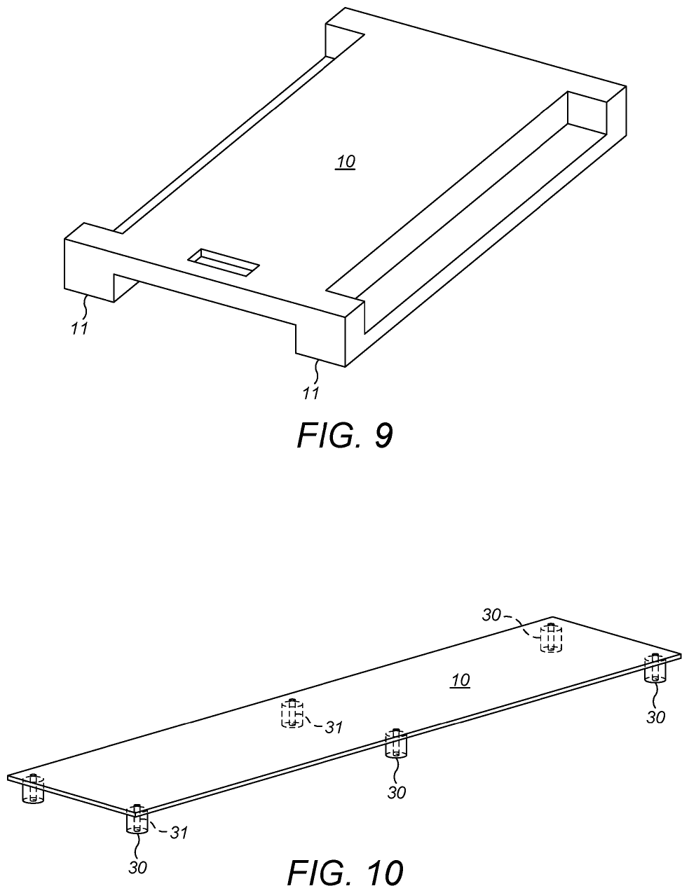

FIG. 9 is a schematic perspective view of an eighth example of a support panel; and

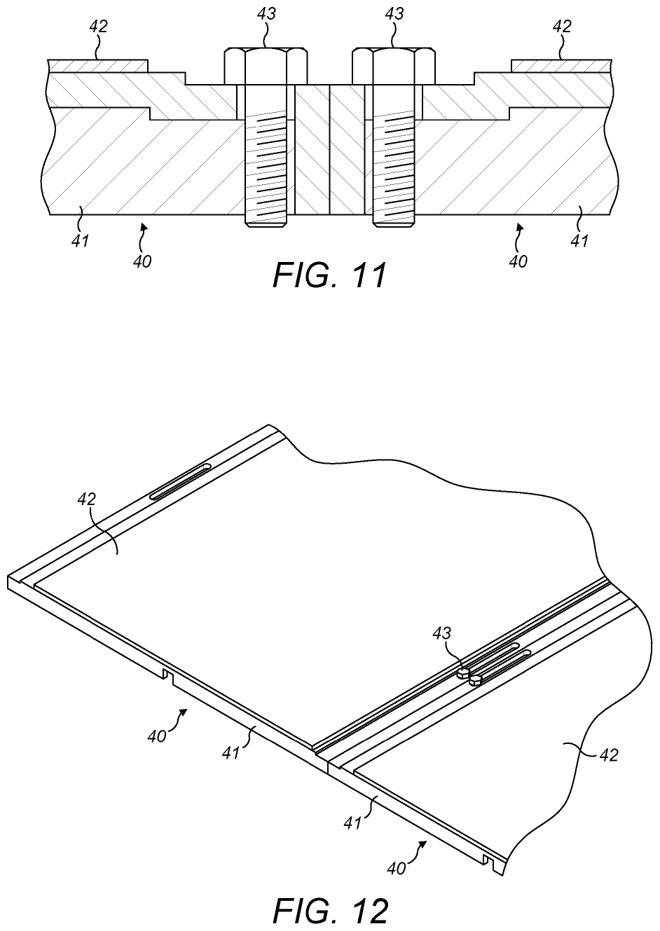

FIG. 10 is a schematic perspective view of a ninth example of a support panel;

FIG. 11 is a cross sectional view through the edges of a pair of panels of a tenth example;

FIG. 12 is a perspective view partially showing the two panels of FIG. 11;

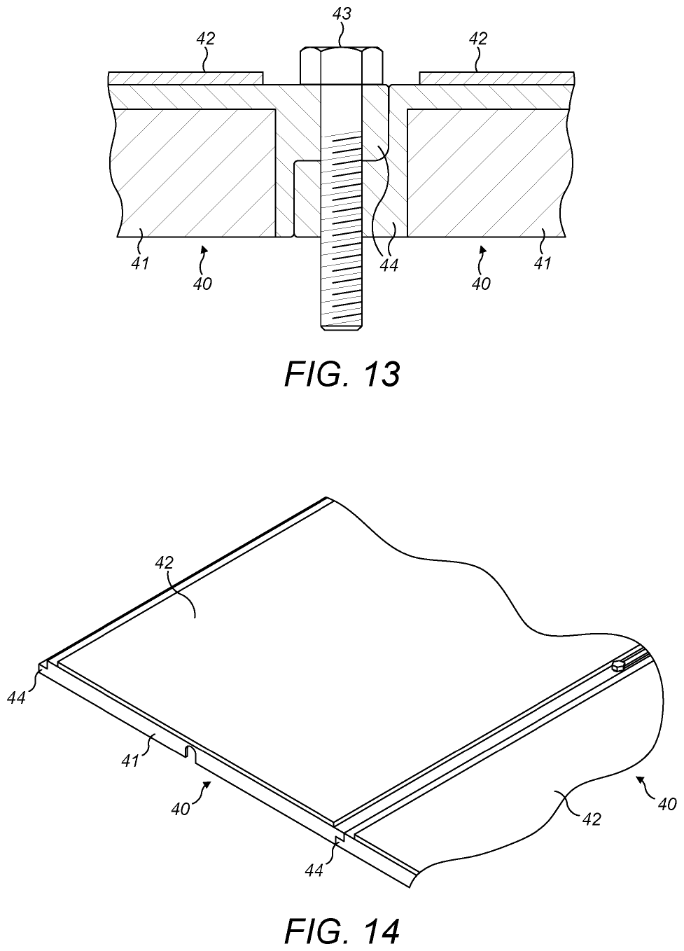

FIG. 13 is a cross sectional view through the edges of a pair of panels of an eleventh example;

FIG. 14 is a perspective view partially showing the two panels of FIG. 13;

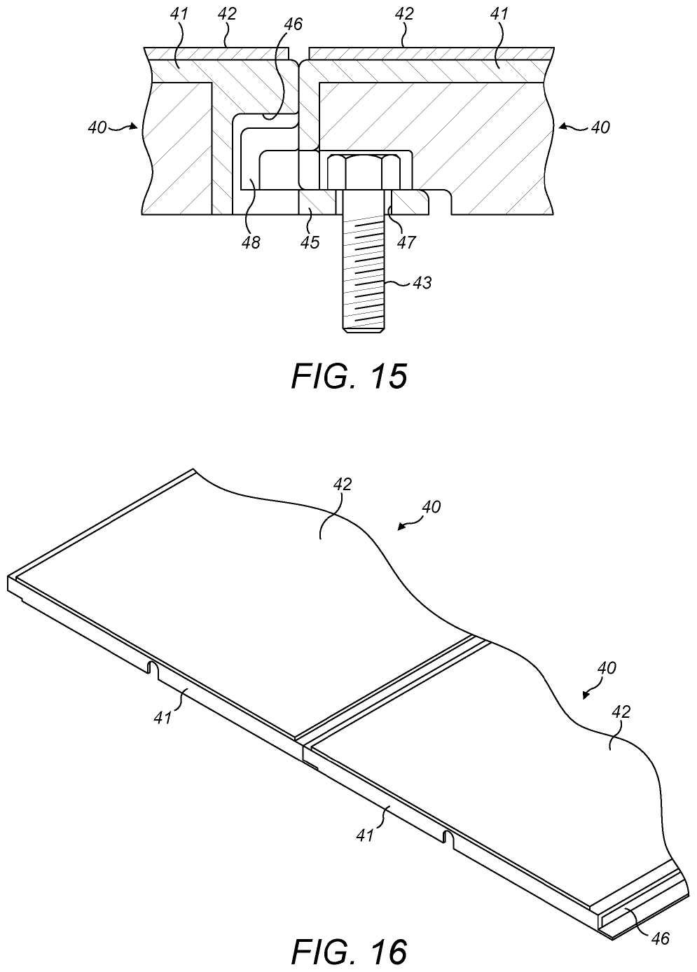

FIG. 15 is a cross sectional view through the edges of a pair of panels of a twelfth example;

FIG. 16 is a perspective view partially showing the two panels of FIG. 15;

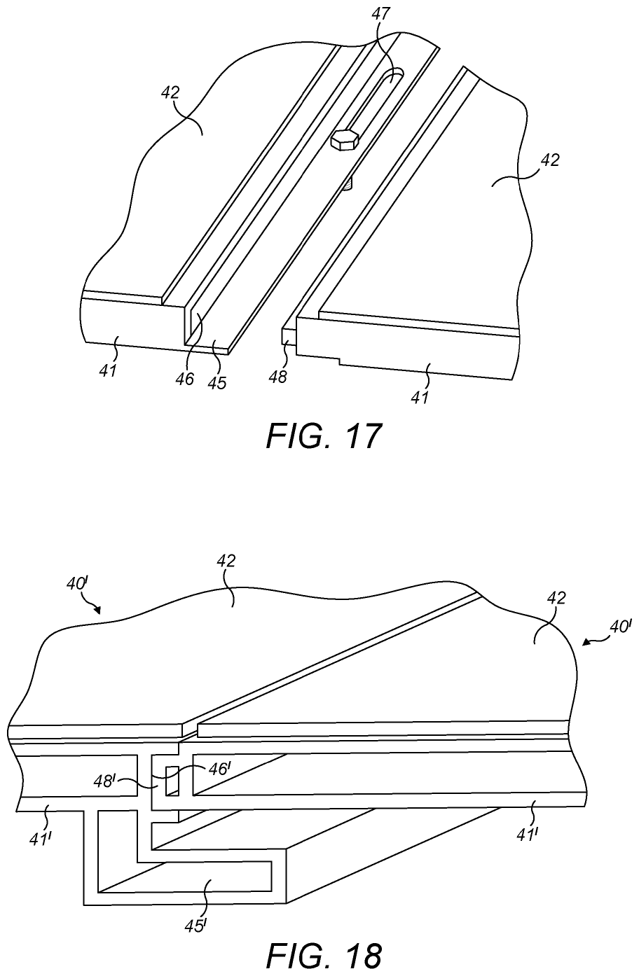

FIG. 17 is a perspective view of the twelfth example shown disassembled;

FIG. 18 is a perspective view through the edges of a pair of panels of a thirteenth example;

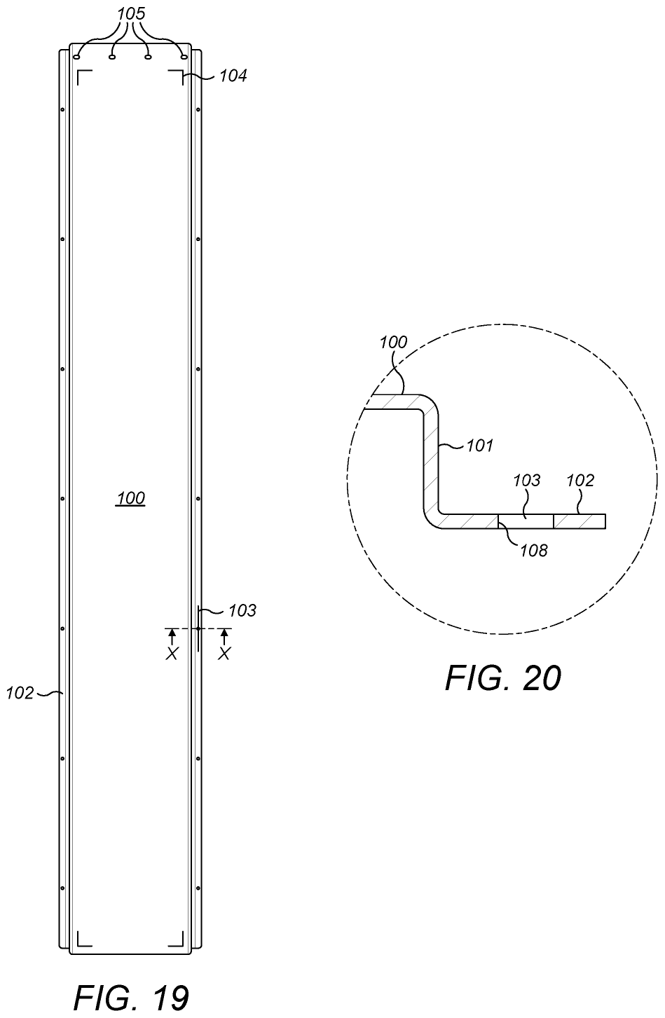

FIG. 19 is a plan view of the support for a panel of a fourteenth example;

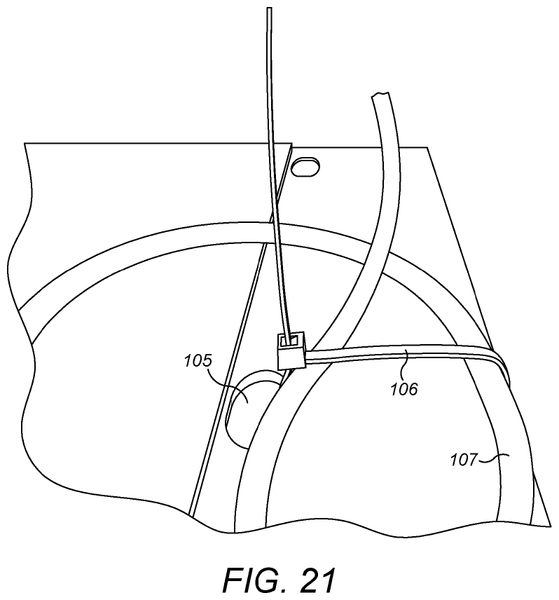

FIG. 20 is a cross section through lone X-X in FIG. 19; and

FIG. 21 is a perspective view of part of the panel of the fourteenth example showing the cable and tie for the panel.

As shown in the drawings, the roof R is a corrugated roof which has a plurality of corrugations creating a number of evenly spaced crests C. As an alternative, the roof could, for example, be any type of roof with an uneven surface, such as a tiled surface, to which it is otherwise difficult to attach flexible solar material directly. There is also no reason why these panels cannot be attached to a flat roof.

The panel comprises three main components, namely a sheet 1 of flexible solar material, a support panel 2 and a layer of adhesive 3 which are described in greater detail below.

The sheet of flexible solar material 1 comprises a photovoltaic layer 4 which is encapsulated between plastic layers 5, 6. The flexible solar material may be any flexible solar material such as amorphous silicon, CdTe, CIGS, GaAs or OPV. It may encompass any solar product that does not have a metal and glass frame and includes crystalline silicon products encapsulated with polymers.

The support panel 2 is formed from a plastic material. Suitable plastic materials include ABS, PC and PVC. These are preferable recycled/recyclable (not PVC) and are fire retardant grades.

The panel 2 is shaped to have a central support layer 10 which is a sheet of material wider than the width of the sheet 1 of flexible solar material. At opposing edges of the support layer 10 is an integrally formed rail 11 which protrudes downwardly from the support layer. The depth of the support rails 11 should be sufficient to allow clearance for the support layer 10 above features on the crests of roof material such as bolts 12 which are present to hold the roof in place. As will be appreciated from FIGS. 1 and 2, the rails run transversely to the crests C of the roof R such that the rails are supported by a plurality of adjacent crests C.

The layer of adhesive 3 adheres the sheet of flexible solar material 1 to the support panel 3 as shown in FIG. 2. This provides a bond between the plastic layer 6 and the plastic support panel 3. Once the solar material is in place, the part of the support panel 3 from which the rails 11 depend extends beyond the sheet of flexible solar material. The panels are pre-formed into this condition for subsequent transportation to the installation site.

In order to create a panel, the manufacturing process is very simple. The flexible solar material 1 is supplied on rolls which are unrolled and cut to length. The panel may be blow moulded, reaction injection moulded, vacuum formed or thermoformed (line bending or die edge forming) of a single sheet, or may be extruded a as single component or as separate components which are subsequently assembled. The sheet of flexible solar material 1 is then simply bonded to the support panel 2 by the adhesive 3. If the panel is metal, it may simply be a flat sheet which has been rolled, punched and/or scored into its final form.

Once on site, each panel, is lifted onto place on the roof. As many panels as required can be put in place as indicated schematically in FIG. 1. These can be spaced in order to avoid any obstructions on the roof and to ensure that they are exposed to sun for as much of the day as possible. Once on the roof, the installer locates the part of the rail which will be above a crest C a drills a hole 13 through the rail 11 onto the roof R. A self-tapping screw is then screwed into each hole. It is not necessary to attach the panel to every crest C. Instead, the installer can make the connections at as many locations as necessary. Alternatively, holes can be pre-drilled in the panel prior to attachment to the roof. As a further alternative the panel can be clamped or glued with an industrial adhesive (such as Teroson MS 939, Loctite SI 5910 or Loctite UK 1367 (all optionally with Teroson 450) in place on the roof.

FIG. 3 shows a second example of a support panel. The support layer 10 and rails 11 are integrally formed as a single vacuumed component. The rails 11 have a U shaped channel section.

FIG. 4 shows a third example of a support panel. This is the same as the second example except that the outer walls of the channel forming the rails 11 have been omitted.

FIG. 5 shows a fourth example of a support panel. This is formed in two parts. The lower part 14 is formed with rails 11 as well as a parallel intermediate rail 15 mid-way between the outer rails 11. A flat upper panel 16 provides the second part and is bonded, for example using ultrasonic welds, heat welds, adhesive or solvent welds to upwardly facing surfaces 17 of the lower part.

FIG. 6 shows a fifth example of a support panel. This is similar to the fourth example but is shown in its finished state. The rails 11 have holes 20 to provide drainage.

FIG. 7 shows a sixth example of a support panel. This shows a lower part 21 of a panel. This may be covered with a flat upper panel as shown in FIG. 6, or there may be sufficient flat surface that the solar material can be bonded directly to this component. In this case the ends of the rails 11, 15 have been capped to prevent the ingress of rain and debris.

FIG. 8 shows a seventh example of a support panel. The rails 11 are extruded box sections. The upper panel 16 is a flat panel similar to that shown in FIG. 6. The rails 11 are bonded to the upper panel 16. Additional intermediate rails 15 may be bonded in place. This example is formed of off the shelf sheeting and box sections.

FIG. 9 shows an eighth example of a support panel. This is a more complex single piece moulding.

FIG. 10 shows ninth example of a support panel. The support layer 10 has a plurality of bosses 30 arranged along opposing edges of the support layer 10. These are pre drilled with holes 31 and this panel therefore does not need to be drilled in situ.

This panel could have one or more intermediate rails 15 or further bosses to provide intermediate support.

The above examples with rails could also be pre-drilled prior to installation.

FIGS. 11 to 18 show examples of how two panels interact at their adjacent edges.

FIGS. 11 to 17 all show adjacent panels 40. These each have a frame 41 and sheet of flexible solar material 42 and are attached to the roof by fasteners 43.

In FIGS. 11 and 12, the panels 40 simply abut one another and are each attached to the roof by their own fasteners 43. The panels 40 can be spaced apart if desired.

In FIGS. 13 and 14, the edges of the panels are provided with complementary lap joints 44. These are arranged so that one set of fasteners 43 passes through the lap joint to fasten both panels to the roof. This significantly reduces the installation time as only half the number of holes and fasteners are required as at an adjoining edge as compared to the example of FIGS. 11 and 12.

The panels have the lap joint features at both edges so that a row of panels can be assembled in this way. The edges of the endmost panels can be held in place with the fasteners passing through the same holes that are shown in FIG. 13, but only in one of the two panels 40.

In FIGS. 15 to 17, the left-hand panel 40 has a more complex edge profile. The lowermost surface has a laterally projecting flange 45, above which is an undercut groove 46 in the end face of the panel. This edge of the panel is first attached to the roof by a set of fasteners 43. As shown in FIG. 17, a groove 47 runs along the flange 45 so that the fastener 43 can be aligned with a crest of the roof. The adjacent panel has a projection 48 with a shape complementary to the undercut groove 46 so that projection 48 can be inserted into the groove 36 to anchor these edges of the adjacent panels together. The second panel has the flange 45 and groove 46 arrangement at its opposite edge so that a row of panels can be assembled in this way.

Each panel 40 has one edge fastened by fasteners 43 and the other edge anchored by the interlocking groove 46 and projection 48. The exposed edge of the endmost panel with the projection 48 may be clamped in place or may have openings for fasteners. As with the previous example, only one set of fasteners is required to anchor the edges of two panels. As shown in FIG. 16, the fasteners do not need to be exposed, so the gap between adjacent solar material 42 can be reduced, thereby providing more solar material for a given roof area.

The example shown in FIG. 18 is similar to that of FIG. 17, but the frame 41′ has a double walled structure to improve the rigidity of the panel 40′. Thus, the flange 45′, groove 46′ and projection 48′ are all present but formed into the double walled structure.

A fourteenth example is shown in Figurers 19 to 21.

This support panel 100 has a cross sectional shape similar to that of the third example shown in FIG. 4. The panel 100 is formed of a single sheet which may be a metal such as aluminium or may be plastic. The sheet is bent down at its edges to form downwardly extending rails 101 which have laterally extending attachment flanges 102.

The flange 102 has a centre line 103 running along its length at its midpoint. As shown in FIG. 20 (and partially in FIG. 19) this is scored but could be drawn or otherwise formed.

The upper face of the panel 100 has markings 104 designating the positions of the corners of the flexible solar sheet. These may be scored, drawn or otherwise formed. These allow the fabricator to align the corners of the flexible solar material to be adhered in place,

Four through holes 105 are provided at one end of the panel to receive cable ties 106 as shown in FIG. 21. These retain the cable 107 which provides the power output from the solar material.

In this example, a single sheet of material which has undergone a number of moulding, forming, punching and/or scoring operations, provides the ability to support the solar material, attach the panel to the roof and retain the cable. This is a very simple and lightweight way of doing this.

The panel 100 is formed with these features and the solar material is adhered in place. The cables 107 are then retained by passing one or more ties 106 through as many holes 105 as necessary.

In that form the panel is transported to the installation site. Once on the roof, the installer identifies an appropriate location for each fastener, drills a hole 108 on the centre line 103 and attaches a fastener as described above. As will be appreciated from FIG. 20, the separation of the drilled hole 108 from the upper surface of the panel 100 provides good dissipation of the heat created while drilling, even if the panel 100 is made of a material such as aluminium. Also, the offset between the upper surface of the panel and the flanges 102 protects the solar material on the upper surface from any material thrown out of the hole 108 in the drilling process.

1. A method of installing a solar panel on a roof,
the solar panel comprising:
a sheet of flexible solar material;
a support panel comprising a support layer and supports formed at opposite edges of the support layer, the supports protruding away from a first side of the support layer and having laterally extending attachment flanges;
an adhesive layer bonding the sheet of flexible solar material on a second side of the support layer opposite to the first side;
the method comprising:
placing the solar panel on the roof;
identifying fixing locations;
drilling holes at the fixing locations in the attachment flanges and roof at at least some of the fixing locations; and
inserting fasteners through the drilled holes to attach the solar panel to the roof.

2. A method of installing a solar panel according to claim 1, wherein the attachment flanges have centrelines marked along their length and the method comprises drilling the holes on the centre line.

3. A method of installing a solar panel according to claim 1, wherein the support panel has at least one through hole at one end and the method further comprises tying a cable to the support panel by passing the tie through the through hole.

4. A solar panel comprising:
a sheet of flexible solar material;
a support panel formed of plastic, the support panel comprising a support layer and supports formed at opposite edges of the support layer, the supports protruding from a first side of the support layer;
an adhesive layer bonding the sheet of flexible solar material on a second side of the support layer opposite to the first side.

5. A solar panel according to claim 4, further comprising one or more intermediate supports positioned between the supports at the opposite edges of the support layer and protruding from a first side of the support layer.

6. A solar panel according to claim 4, wherein the panel is formed of a lower part comprising the supports and an upper part bonded to the lower part and having a flat upper face to provide the second side of the support layer.

7. A solar panel according to claim 1, wherein the supports at the opposite edges of the support are a pair of rails.

8. A solar panel according to claim 7, wherein the rails are formed to have an open channel section.

9. A solar panel according to claim 8, wherein the ends of the rails are capped to prevent ingress of water and debris.

10. A solar panel according to claim 8, wherein the rails are provided with drainage holes.

11. A solar panel according to claim 8, wherein wiring for the solar material is routed along the rails.

12. A solar panel according to claim 1, wherein the sheet of flexible solar material is encapsulated in a plastics material.

13. A solar panel according to claim 1, wherein the part of the support panel from which the supports at opposite edges of the support layer depend extends beyond the sheet of flexible solar material.

14. A solar panel according to claim 1, wherein the support panel is made from recycled plastic.

15. A solar panel according to claim 1, wherein an edge of the support panel has a first engagement feature to interlock with a complementary second engagement feature of an adjacent panel.

16. A solar panel according to claim 15, wherein the support panel has the first engagement along a first edge and the second engagement feature along a second edge opposite to the first edge.

17. A solar panel according to claim 16, wherein the first engagement feature is configured to receive a fastener which, in use, will pass through a space in the engagement feature configured to receive the adjacent panel.

18. A solar panel according to claim 16, wherein the first engagement feature is configured to retain the engagement feature of an adjacent panel, and the panel is configured to receive a fastener which, in use, will pass through the panel, but not a space occupied, in use, by an adjacent panel engaged with the engagement feature.

19. A solar panel comprising:
a sheet of flexible solar material;
a cable electrically connected to the solar panel for the transmission of power from the solar material;
a support panel comprising a support layer and supports formed at opposite edges of the support layer, the supports protruding away from a first side of the support layer;
an adhesive layer bonding the sheet of flexible solar material on a second side of the support layer opposite to the first side;
wherein the support panel has at least one through hole at one end;
and a tie passing through the through hole to tie the cable to the support panel.

20. A solar panel according to claim 20, further comprising laterally extending attachment flanges extending from the supports via which the panel is attached to a roof.

21. A solar panel comprising:
a support panel comprising a support layer and supports formed at opposite edges of the support layer, the supports protruding from a first side of the support layer;
a sheet of flexible solar material attached on a second side of the support layer opposite to the first side
wherein an edge of the support panel has a profiled shape forming a first engagement feature to interlock with a complementary second engagement feature of an adjacent panel.

22. A solar panel according to claim 21, wherein the support panel has the first engagement along a first edge and the second engagement feature along a second edge opposite to the first edge.

23. A solar panel according to claim 22, wherein the first engagement feature is configured to receive a fastener which, in use, will pass through a space in the engagement feature configured to receive the adjacent panel.

24. A solar panel according to claim 22, wherein the first engagement feature is configured to retain the engagement feature of an adjacent panel, and the panel is configured to receive a fastener which, in use, will pass through the panel, but not a space occupied, in use, by an adjacent panel engaged with the engagement feature.

25. A combination of a solar panel according to claim 1 and a plurality of fasteners for fastening the panel to a roof.

26. A method of attaching a solar panel according to claim 1 to a pre-existing roof.
